(19) United States
(12) Patent Application Publication
(10) Pub. No.: US 2008/0236744 A1
(43) Pub. Date: Oct. 2, 2008

(54) Plasma etching equipment

(76) Inventors: Muneo Furuse, Kudamatsu (JP); Shingo Kimura, Shunan (JP); Tadayoshi Kawaguchi, Kudamatsu (JP)

Correspondence Address: MCDERMOTT WILL & EMERY LLP, 600 13TH STREET, N.W., WASHINGTON, DC, 20005-3096, US

(21) Appl. No.: 11/896,293

(22) Filed: Aug. 30, 2007

(30) Foreign Application Priority Data
Mar. 30, 2007 (JP) 2007-090141

(51) Int. Cl. H01L 21/306

(52) U.S. Cl. 156/345.1

(57) ABSTRACT

To provide a plasma processing equipment that can reduce the particles or contamination in a sample by suppressing the occurrence of an abnormal electric discharge during processing. The plasma processing equipment that employs a plasma process using a halogen-based gas in fabricating a semiconductor device, wherein a plasma sprayed coating film is applied to a surface of a well, such as a wall in a processing chamber, which plasma is in constant with, and wherein a conductor is incorporated into a material of this plasma sprayed coating film, thereby making the plasma sprayed coating film conductive.

### INCORPORATION BY REFERENCE

The present application claims priority from Japanese application JP2007-090141 filed on Mar. 30, 2007, the content of which is hereby incorporated by reference into this application.

### FIELD OF THE INVENTION

The present invention relates to a plasma processing equipment that processes a substrate-shaped sample, such as a semiconductor wafer, arranged inside a processing chamber in a vacuum vessel using plasma formed in this processing chamber. In particular, the present invention relates to the plasma processing equipment that includes inside the processing chamber a member having a potential of a predetermined value with respect to the plasma.

### BACKGROUND OF THE INVENTION

As the conventional plasma etching equipment, as described in JP patent Appln. No. 11-351546 (JP-A-2001-164354) (Patent Document 1), it is known that the coating of the surface of a processing chamber container with a plasma sprayed coating of Y₂O₃ or the like having a porosity of 5% to 10% will improve the plasma resistance. Because in this conventional art the surface of the processing chamber contacting the plasma is coated with the plasma sprayed coating of Y₂O₃ or the like, a damage due to the plasma is also reduced and thus an undercoat for covering the surface of a base material is formed in a thickness of 50 to 500 μm using a metallic film. Moreover, the roughness of the surface of the base material to be coated with a plasma sprayed coating film is formed such that a film by spraying may adhere to the surface easily.

However, in this conventional art, if the plasma is actually generated, the potential of a member as a ground electrode with respect to the plasma inside the processing chamber will be raised. Namely, because the surface of the member intended to act as the ground electrode arranged on the surface inside the processing chamber, the surface of the member contacting the plasma, is coated with a highly insulative material in order to suppress chipping and corrosion due to the plasma, there is a problem that the potential of the plasma can not be stabilized because the surface of this member can not be set to the earth potential with respect to the plasma. In order to solve this problem, as disclosed in JP-A-2005-183833 (Patent Document 2), a technique has been considered, in which the interior of the processing chamber is provided with a member whose surface is composed of an electrically conductive material, and a portion with this electrical conductivity is electrically conductibly coupled to a portion of a vacuum vessel, the portion being connected to the ground, and this member is used as a direct current (DC) earth with respect to the plasma.

### (Patent Document 1) JP-A-2001-164354

### (Patent Document 2) JP-A-2005-183833

### BRIEF SUMMARY OF THE INVENTION

Generally, in the manufacturing process of a semiconductor device, a liquid crystal device, and the like, a process gas including a fluoride such as BF₃ or NF₃, a chloride such as BCl₃ or SnCl₄, or a bromide such as HBr is used inside the processing chamber, and therefore there is a problem that an inner wall material of an etching processing chamber is corroded and worn significantly. For example, with regard to the material currently used for the inner wall of the etching processing chamber of a semiconductor manufacturing equipment, a method is known, in which a metallic material, such as Al, an aluminum alloy, and a stainless alloy, is used as the base material and then the surface thereof is coated with an anodized film of Al, or with a plasma sprayed coating of a boron carbide, alumina, or the like, or with a sintered film of Al₂O₃ or Si₃N₄, or furthermore with a polymer film of fluororesin, an epoxy resin, or the like.

Upon contact with highly corrosive halogen ions, these materials are subjected to chemical damage to thereby produce microparticles of SiO₂, Si₃N₄, and the like. Moreover, it is also known that these materials are subjected to erosion damage due to ions excited by the plasma. In particular, in an etching process using a gas of a halogenated compound, plasma is often used in order to achieve further activation by reaction. However, under such environment using plasma, the halogenated compound is dissociated to produce extremely highly corrosive atomic F, Cl, Br, and the like, and also if a fine powder-form solid of SiO₂, Si₃N₄, Si, W, or the like is present in this environment, a member used inside the plasma processing chamber is subjected to chemical corrosion as well as to erosion damage due to the microparticles, resulting in being subjected to the so-called erosion-corrosion effect, strongly. In addition, it is also known that in an environment in which plasma processing chamber, a phenomenon (ion bombardment) occurs in which even a non-corrosive gas such as an Ar gas is ionized and this ion collides with the plasma processing chamber surface strongly, and thus various kinds of members arranged inside the above-described chamber are bombarded to further stronger damage.

As described above, in Patent Document 1, for the purpose of keeping constant the potential of the plasma to be generated in order to perform the etching work inside the processing chamber, sufficient care has not been taken. For this reason, the potential of the plasma tends to be unstable, thus causing a problem that a slight change of properties or a crack in the surface of the member contacting the plasma inside the processing chamber occurs, or that an abnormal electric discharge tends to occur in a portion where the plasma sprayed coating film is thin or the like, and thus chipping or corrosion will progress.

That is, when aluminum or an aluminum alloy is used as the base material of the processing chamber and the surface of the processing chamber is coated with quartz or ceramics, or when ceramics, such as Al₂O₃ or Y₂O₃, is sprayed to a stainless alloy or aluminum alloy for coating, it is difficult to keep constant the potential of the plasma generated inside the processing chamber. That is, with an increase in the discharge duration, the plasma potential will be raised, and if the plasma potential reaches equal to or greater than a certain potential, a local electric discharge may occur. In this case, the discharge occurs at a portion where the plasma sprayed coating film is weakest. Once this discharge started, the plasma generated inside the processing chamber regards this portion as the earth and thus a large current will flow locally. As a result, in this portion a metal of the base material is directly in contact with the plasma, and a contaminating material, such as a stainless alloy or an aluminum, will be diffused into the plasma, and in some cases the stainless alloy or aluminum alloy portion may melt.

On the other hand, in the technique of Patent Document 2 attempting to solve this, an electrically conductive material (electrically conductive ceramics, SiC, aluminum, an aluminum compound) is attached to about 10% of the surface area inside the processing chamber in order to secure the area of the ground electrode required for stabilizing the potential of the plasma. However, it is difficult to arrange such a large area of conductive member inside the processing chamber, because such highly electrically conductive material has a high efficiency of interaction also with the particles within the plasma and thus chemical and physical reactions progress and the chipping or erosion easily progresses. As a result of such interaction, if the particles of the material forming this member are discharged to the interior of the processing chamber in large quantities, these particles will adhere to the substrate surface of a semiconductor wafer or the like to be processed, resulting in foreign substances.

In either case, the material forming the base material of the member, such as a stainless alloy or an aluminum alloy, comes in contact with the plasma generated inside the processing chamber, and thereby a metallic contamination material, such as Fe or Al, which diffuses into the plasma, will deposit on the wafer during etching process, thus causing a wiring defect of a semiconductor device or the like that is fabricated with this etching equipment.

It is an object of the present invention to provide a plasma processing equipment that can reduce particles or contamination in a sample by suppressing the occurrence of an abnormal electric discharge during processing.

The above-described object is achieved by electrically grounding the surface that covers the inner wall of a processing chamber of the plasma processing equipment and thereby not allowing the potential of the plasma generated inside the processing chamber to be raised.

More specifically, the above-described object is achieved by a plasma processing equipment that employs a plasma process using a halogen-based gas in fabricating a semiconductor device, wherein a sprayed deposit is applied to the surface of a wall, such as a wall in a processing chamber, which plasma is in constant with, and wherein a conductor is incorporated into a material of this sprayed deposit, thereby making the plasma sprayed coating conductive.

Moreover, the above-described object is achieved by that a material sprayed to the wall member inside the plasma processing equipment is composed of either one type, or two or more types out of Al₂O₃, YAG, Y₂O₃, Gd₂O₃, Yb₂O₃, and YF₃, and that a conductor is incorporated into this sprayed material. Furthermore, the above-described object is achieved by that the conductor incorporated into the member that is sprayed to the surface of the wall of the plasma processing equipment is composed of either one type, or two or more types out of carbon, cobalt, iridium, molybdenum, nickel, osmium, palladium, platinum, rhodium, ruthenium, tantalum, thorium, titanium, vanadium, tungsten, yttrium, and zirconium.

Furthermore, the above-described object is achieved by that the volume resistivity of the material sprayed to the surface of the wall of the plasma processing equipment is set to no more than 100 Ω·cm. Furthermore, the above-described object is achieved by that the material sprayed to the surface of the wall of the plasma processing equipment is coated by plasma spray or by low pressure plasma spraying.

Furthermore, the above-described object is achieved by that the material composed of a conductor, such as a stainless alloy or an aluminum alloy, is used for the base material of the plasma sprayed coating film covering the wall, which the plasma is in contact with.

Moreover, the above-described object is achieved by a plasma processing equipment that employs a plasma process using a halogen-based gas in fabricating a semiconductor device, wherein in a surface of a wall, which plasma is in contact with, such as a wall inside a processing chamber, a sintered ceramic such as alumina, into which either one type, or two or more types of conductors out of carbon, cobalt, iridium, molybdenum, nickel, osmium, palladium, platinum, rhodium, ruthenium, tantalum, thorium, titanium, vanadium, tungsten, yttrium, and zirconium are incorporated, is used.

Moreover, the above-described object is achieved by a plasma processing equipment that employs a plasma process using a halogen-based gas in fabricating a semiconductor device, wherein in a surface of a wall, which plasma is in contact with, such as a wall inside a processing chamber, quartz, into which either one type, or two or more types of conductors out of carbon, cobalt iridium, molybdenum, nickel, osmium, palladium, platinum, rhodium, ruthenium, tantalum, thorium, titanium, vanadium, tungsten, yttrium, and zirconium are incorporated, is used.

Moreover, the above-described object is achieved by a plasma processing equipment that employs a plasma process using a halogen-based gas in fabricating a semiconductor device, wherein in a surface of a wall, which plasma is in contact with, such as a wall inside a processing chamber, a plasma resistant resin, into which either one type, or two or more types of conductors out of carbon, cobalt, iridium, molybdenum, nickel, osmium, palladium, platinum, rhodium, ruthenium, tantalum, thorium, titanium, vanadium, tungsten, yttrium, and zirconium are incorporated, is used.

Other objects, features and advantages of the invention will become apparent from the following description of the embodiments of the invention taken in conjunction with the accompanying drawings.

### BRIEF DESCRIPTION OF THE DRAWINGS

FIG. 1 is a vertical cross-sectional view showing a plasma etching equipment that is an example of the present invention.

FIG. 2 is a cross sectional view of a processing chamber of the plasma etching equipment that is the example of the present invention.

FIG. 3 is a vertical cross-sectional view showing an example that uses a plasma sprayed coating film containing an electrically conductive material in a part of the processing chamber of the plasma etching equipment that is the example of the present invention.

FIG. 4 is a vertical cross-sectional view showing an example that uses ceramics containing an electrically conductive material in a part of processing chamber of the plasma etching equipment that is the example of the present invention.

FIG. 5 is a vertical cross-sectional view showing an example that uses a plasma resistant resin containing an electrically conductive material in a part of the processing chamber of the plasma etching equipment that is the example of the present invention.

### DESCRIPTION OF REFERENCE NUMERALS)

100 Processing chambers
101 Lid member
102 Antenna
103 Magnetic field generator
105 Radio source part
106 Dielectric substance
107 Quartz plate
108 Shower plate
109 Sample stage
110 Processing chamber
116 Processing chamber wall member
117, 118 Plasma sprayed coating film
119 Sintered ceramic
120 Plasma resistant resin
121 Inner chamber
131 Exhaust valve
132 Vacuum pump
150 Wafer
200 Plasma

### DETAILED DESCRIPTION OF THE INVENTION

A plasma processing equipment concerning an embodiment of the present invention can stabilize the potential of the plasma generated inside a processing chamber by causing a processing chamber inner wall to have both plasma resistance and electrical conductivity. Specially, the arrangement of a DC earth inside the processing chamber will eliminate a rise of the potential of the plasma used in the etching process. As a result, a local electric discharge or the like will not occur in the plasma generated in the processing chamber. Moreover, the surface of a member contacting the plasma inside the processing chamber is covered with a film (hereinafter, referred to as a plasma sprayed coating) formed by spraying, in which an electrically conductive material is distributed and arranged substantially uniformly, and this member is disposed under a sample, such as a semiconductor wafer, placed on a sample stage where a processing such as etching is carried out, or this member is disposed downstream in the direction that particles such as the plasma inside the processing chamber flow to be discharged, whereby even if the wall with the plasma sprayed coating film is worn out by sputtering or the like, the amount of metallic contamination on a wafer, in which semiconductor devices or the like are fabricated, will not increase. That is, the particles or contaminant associated with the plasma used in the etching process will not come flying onto the wafer, to which processing such as etching is carried out, and thus a defect caused by the particles or contamination will not occur when fabricating the semiconductor device or the like.

In this way, when carrying out an etching processing of a Si wafer or the like for fabricating a semiconductor device, by means of a plasma sprayed coating film containing an electrically conductive material on the surface of the member, which is arranged inside the processing chamber in a vacuum vessel and which the plasma is in contact with, the potential of the plasma generated inside the processing chamber is stabilized so as not to cause an abnormal electric discharge or the like inside the processing chamber. In the plasma processing equipment, halogen-based corrosive gases are used in the etching process and thus the processing chamber inner wall will be always exposed to these gases. Accordingly, the processing chamber inner wall should be made of a material with corrosion resistance against the halogen-based gases and with plasma resistance. The material with plasma resistance and corrosion resistance is typically quartz or a ceramic material composed of oxides, such as SiO₂ or Al₂O₃, or a fluoride such as AlF₃ that is less reactive with the plasma, and these are low electrical conductive materials. If the processing chamber inner wall is formed with these materials, the so-called abnormal electric discharge, where the potential of the plasma generated inside the processing chamber is raised and an electric discharge concentrates on a part of the processing chamber inner wall frequently occurs. For the purpose of eliminating this abnormal electric discharge, if the material constituting the member of the processing chamber inner wall is made a highly electrical conductive material and this inner wall is electrically coupled to a portion connected to the earth, then the surface of this member will be chipped by the plasma used in the etching process and electrically conductive materials will be discharged into the plasma. As a result, a lot of electrically conductive materials chipped by the plasma will be present inside the processing chamber, and thus in a wafer to be processed in this processing chamber the foreign substances composed of the electrically conductive materials and the contamination will cause problems.

In the etching equipment of this embodiment, the potential of the plasma generated inside the processing chamber is stabilized and an abnormal electric discharge will not occurs because a plasma sprayed coating film containing an electrically conductive material is employed as a film covering the surface of the member composed of an electrically conductive material, the member being used inside the processing chamber. Moreover, because the electrically conductive material is incorporated into a highly plasma resistant plasma sprayed coating film, the plasma sprayed coating film will not be chipped off a lot and the electrically conductive material will not be splashed a lot into the processing chamber. Moreover, the use of the plasma sprayed coating film of such structure in the material of the processing chamber inner wall will eliminate an abnormal electric discharge occurring inside the processing chamber, and will reduce a fluctuation (of the rate, shape, or the like) in the etching process and the particles due to the plasma instability caused by the abnormal electric discharge, and will suppress the contamination caused by the particles.

More specifically, the plasma processing equipment concerning this embodiment employs a plasma process using a halogen-based gas in fabricating a semiconductor device, wherein the sprayed deposit covering the surface of the member, which the plasma inside the processing chamber is in constant with, is a highly plasma resistant material, into which an electrically conductive member is incorporated and is uniformly arranged, and wherein a film of the plasma sprayed coating film has electrical conductivity. Moreover, the film covering the surface of the member inside the processing chamber is formed by plasma spraying a material obtained by incorporating an electrically conductive material into a material constituting the principal component composed of either one type, or two or more types out of Al₂O₃, YAG, Y₂O₃, Gd₂O₃, Yb₂O₃, and YF₃, and then by distributing these substantially uniformly. Such film by plasma spraying is formed by plasma spray or by low pressure plasma spraying.

Moreover, the electrically conductive material incorporated into the member to be sprayed onto the surface of the wall of the plasma processing equipment is composed of either one type, or two or more types out of carbon, cobalt, iridium, molybdenum, nickel, osmium, palladium, platinum, rhodium, ruthenium, tantalum, thorium, titanium, vanadium, tungsten, yttrium, and zirconium. Moreover, for the film that covers the surface of the thus-arranged member inside the processing chamber against the plasma, the volume resistivity thereof is set equal to or less than 100 Ω·cm.

Moreover, for the member constituting the inner wall of the above-described processing chamber and contacting the plasma, the one obtained: by forming a film by plasma spraying a material constituting the principal component composed of either one type, or two more types out of the above-described Al₂O₃, YAG, Y₂O₃, Gd₂O₃, Yb₂O₃, and YF₃ onto the surface of the base material of the member; and thereafter by impregnating a solution, into which the above-described electrically conductive material is mixed, into the member covered with the plasma sprayed coating film made of the above-described principal member, may be used. Alternatively, the one obtained by plasma spraying a material of the above-described principal component and an electrically conductive material alternately to the surface of the base material of the member may be used.

Alternatively, the one obtained by calcinating the above-described member whose surface is coated with a raw material, the raw material being obtained by mixing a material serving as the above-described principal component and an electrically conductive material together so that the both are distributed substantially uniformly, may be used. Alternatively, quartz or a plasma resistant resin, inside which an electrically conductive material is distributed and arranged substantially uniformly, may be used. Moreover, as the base material of the member inside such processing chamber, a material made of a conductor, such as a stainless alloy or an aluminum alloy, can be used.

### EXAMPLES

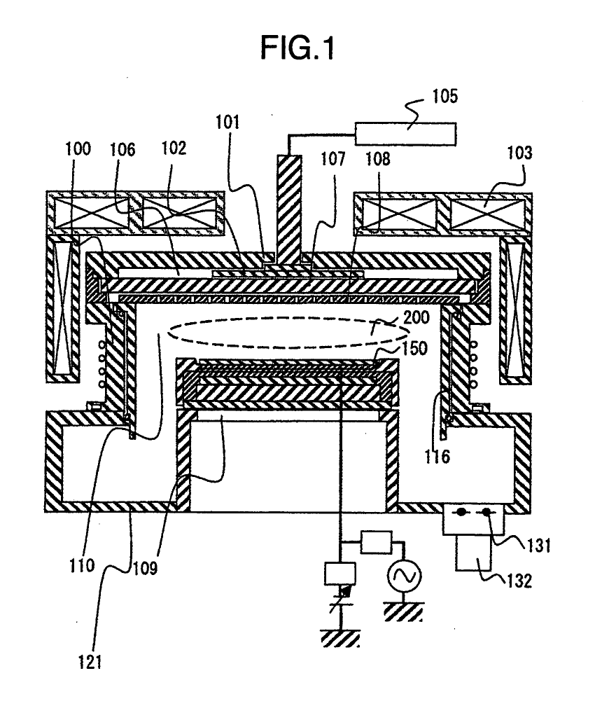

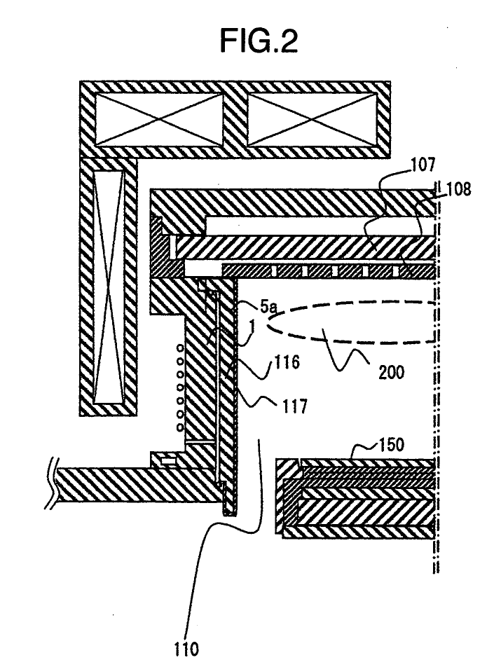

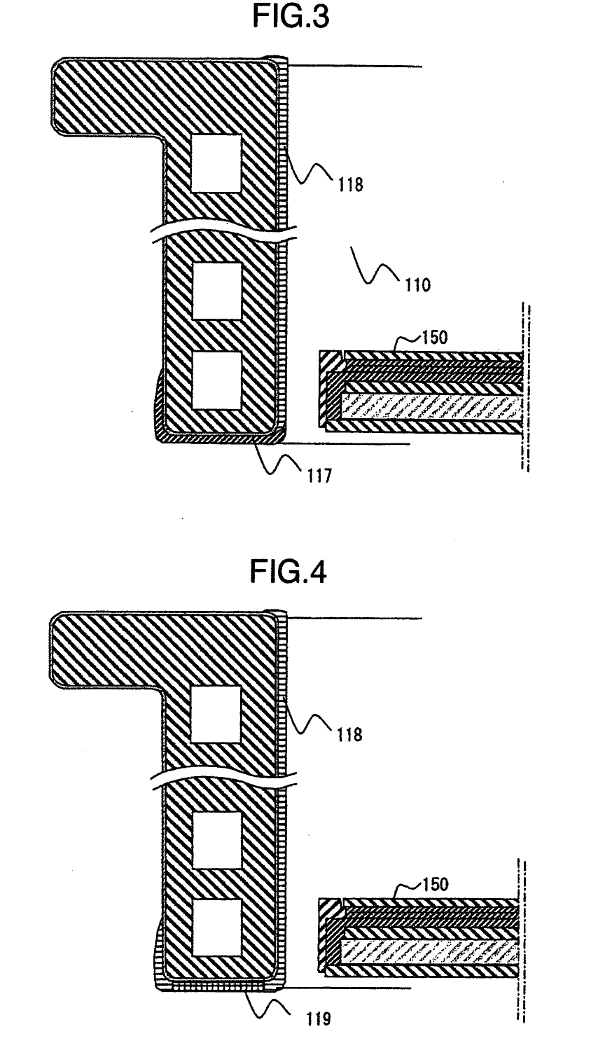

Hereinafter, an example of the present invention will be described using FIG. 1, FIG. 2, and a FIG. 3 and FIG. 4. FIG. 1 is a vertical cross-sectional view showing a configuration of a chamber part of a processing unit.

As shown in this view, a processing chamber is disposed in the upper part of processing chambers 100, and this processing chamber comprises: a lid member 101 constituting a lid of a vacuum vessel; an antenna 102 disposed inside this lid member 101; a magnetic field generator 103 disposed on the side of and above this antenna 102 and disposed surrounding the processing chamber; and a ceiling member disposed under this antenna 102. Moreover, above the magnetic field generator 103 there is disposed a radio source part 105 for supplying an electric power for VHF and UHF band frequency from 200 MHz to 1 GHz, which the antenna 102 radiates. The antenna 102 to supply is disposed inside the lid member 101 composed of an electrically conductive member, such as SUS, and between the antenna 102 and the lid member 101 there is disposed a dielectric substance 106 for isolating between the antenna 102 and the lid member 101 and for conducting the radio wave radiated from the antenna 102 to the lower ceiling member side.

Moreover, the ceiling member includes: a quartz plate 107 composed of a dielectric substance, such as quartz, for conducting the transmitted radio wave to the interior side of a lower processing chamber; and a shower plate 108, in which a plurality of holes for dispersing and introducing the supplied process gas used for processing to the interior of the processing chamber are formed, the shower plate 108 being disposed under the quartz plate 107.

A space formed under the shower plate 108 and above a sample stage 109 is a processing chamber 110, in which plasma is formed from a supplied process gas by an interaction between a radio wave from the antenna 102 introduced through the shower plate 108 and a magnetic field supplied from the magnetic field generator 103. In the processing chamber 110, the process gas is dispersed and introduced into the processing chamber 110 from a plurality of holes provided in the shower plate 108, and these holes are arranged mainly in a position opposite to a position where a sample is mounted on the sample stage 109, thus allowing the gas to be dispersed as to be more uniform and allowing the density of plasma to be made uniform.

Moreover, under the shower plate 108 there is provided a processing chamber wall member 116 that divides the space of the processing chamber 110, the processing chamber wall member 116 facing the plasma inside the vacuum chamber. In the outer peripheral surface of this processing chamber wall member 116, a heater is wound and arranged therearound. The sample stage 109 is disposed in an inner chamber 121, and an opening is disposed in the inner chamber 121. This opening is located in the lower part of the inner chamber 121, and is communicating with an exhaust means provided with an exhaust valve 131 and a vacuum pump 132, thus allowing the processing chamber 110 and the inner chamber 121 to be evacuated.

In this system configuration, by employing a plasma sprayed coating film containing an electrically conductive material in a part of the side wall of the processing chamber 110, the potential of the plasma generated inside the processing chamber 110 is stably generated without being raised by continuous electric discharging or the like. As a result, an abnormal electric discharge which raises the potential of the plasma and which directly hits a part of the plasma sprayed coating film will not occur.

FIG. 2 is an enlarged view near the surface of the processing chamber wall member 116 of the processing chamber 110 shown in the example of FIG. 1. This view is an example, in which the surface of the processing chamber wall member 116 is coated with a plasma sprayed coating film 117 containing an electrically conductive material. According to this view, the plasma sprayed coating film includes as the principal component a material, such as ceramics, having high corrosion resistance and low reactivity with respect to the plasma, and in this example the plasma sprayed coating film is formed of the principal component with a proportion of 90 to 95 weight % or more. Such a configuration will not allow a plenty of particles and contaminated substances to be discharged even if a plasma 200 generated inside the processing chamber 110 comes in constant with the plasma sprayed coating film 117 in the surface of the processing chamber inner wall 116. As a result, it is possible to reduce the particles and the quantity of contaminant that splash above a wafer 150, in which semiconductor devices are fabricated, and possible to manufacture semiconductor devices with few defects efficiently.

The materials protecting the processing chamber inner wall may include: an anodized film for covering the surface of quartz, ceramics, such as alumina or an aluminum alloy; a plasma sprayed coating film for covering the surface of a stainless alloy or an aluminum alloy with ceramics. In this example, in applying a film by spraying to the surface of an aluminum alloy, or to the surface of a stainless alloy, a ceramic powder, which is the material of the film, is inserted into the plasma. Then, after the ceramic powder is melted, the ceramic powder is caught in the flow of the plasma jet and reaches the surface of a target to be coated.

Here, if the melting point of the material, e.g., a metal, to be incorporated into ceramics, the material giving electrical conductivity to the film, is too low, the particles of this material are melted and a plurality of particles couple together into a large lump, which distributes into the film. As a result, the electrically conductive material will be arranged biased toward a part of the film, and the thickness of the ceramics existing from the surface of the film of this portion to the lump of this material becomes thin locally, and thus an abnormal electric discharge in this portion easily occurs. Once an abnormal electric discharge occurred, the chipping or corrosion in this portion progresses, and finally the metal lump will get exposed to the interior of the processing chamber, resulting in a contamination source for the sample.

For this reason, in this example, a metal incorporated into a ceramic sprayed deposit made of alumina or the like, the sprayed deposit covering the inner wall of the etching equipment, the metal being composed of a stainless alloy or an aluminum alloy, is a refractory metal. As a result, inside the plasma sprayed coating film containing ceramics as the principal component, the particles of an electrically conductive metal with a high-melting point will be distributed almost uniformly between the particles of the ceramics laminated in layers. Moreover, the diameter of the particle of ceramics serving as the principal component is made larger than that of the particle of the electrically conductive material, and in a layer structure of films which the large particles of the principal component constitute by linking the melted surfaces thereof with each other, a small particles enters into a space or a pore between the large particles and is fixed therein. For this reason, the layer structure is not susceptible to the interaction from the plasma, thus suppressing an abrupt decrease in the conductivity of the film.

Moreover, the particles of ceramics composed of a metal oxide strongly adheres to the concaves and convexes formed in the surface of the material of an electrically conductive metal, such as aluminium or stainless, which is the base material of the member, and thereby the peeling of the film is suppressed and at the same time the position of an electrically conductive metallic particle arranged between the particles of ceramics is fixed so that free electrons may move easily between the particles and between the particles and the surface of the base material.

For this reason, the member electrically coupled to the wall member of the vacuum chamber, the wall member having such a sprayed deposit in the surface thereof and being connected to the ground, will act as an electrode for taking a predetermined potential with respect to the potential of the plasma generated inside the processing chamber. In particular, the member will act as a direct current (DC) earth, the potential of which is stabilized and the variation of the potential is suppressed.

Moreover, by increasing the atomic weight of the metal incorporated into the plasma sprayed coating film, the wearing out of the metal as well as the splashing into the plasma due to sputtering can be suppressed. However, in the case where the ceramic plasma sprayed coating film containing a metal is arranged at a portion which a high density plasma comes in constant with, the amount of the plasma sprayed coating film as well as the chipped amount of the metal incorporated into the plasma sprayed coating film will increase, and as a result the metal amount discharged from the plasma sprayed coating film will also increase. In the case where such plasma is used, the position of the earth coated with the plasma sprayed coating film containing a conductor, such as a metal, of the present invention is arranged on the exhaust side of the electrode for carrying out etching or the like of a wafer, in which semiconductor devices or the like are fabricated, and thereby the potential of the plasma generated inside the processing chamber can be kept constant and the amount of metallic contamination that comes flying onto the wafer can be reduced.

For this plasma sprayed coating film containing a conductor such as a metal, the same effect can be expected also in quartz containing a conductor, ceramics containing a conductor, and a plasma resistant resin containing a conductor, e.g., polymer materials (dielectric constant k∈ is about 2.1 to 4.2), such as polyamidoimide, polyether ether ketone, polyimide, polyetherimide, polytetrafluoroethylene, and polybenzimidazole, in place of the sprayed deposit.

FIG. 3 shows an example, in which when flowing a gas from the shower plate, the gas being used in the etching process, a plasma sprayed coating film 117 containing an electrically conductive material is arranged downstream of the wafer 150, in which semiconductor devices are fabricated. Note that a plasma sprayed coating film 118 not containing an electrically conductive material is used upstream of the wafer 150, in which semiconductor devices are fabricated. According to this example, even if the plasma sprayed coating film 117 containing an electrically conductive material is chipped off by the plasma 200 generated inside the processing chamber 110, particles caused by the chipped material is caught in the flow of the process gas and is evacuated and thus the particles will not be splashed onto the wafer 150. In the equipment configured as described above, the splashing of particles onto the wafer 150, to which processing such as etching is carried out, will be eliminated and also the quantity of contaminant caused by the particles will be reduced, and thus semiconductor devices with few defects can be manufactured efficiently.

FIG. 4 is an example, in which a member composed of a sintered ceramic 119, such as alumina, containing an electrically conductive material is used for a part of the processing chamber wall member 116. Although in this example alumina (Al₂O₃) is used for the base material containing an electrically conductive material, the base material may be a metal oxide (ceramics of ZrO₂, MgO, YAG, Y₂O₃, or the like). By using the sintered ceramic 119, such as alumina, containing this electrically conductive material in a part of the processing chamber inner wall, the potential of the plasma 200 generated inside the processing chamber 110 will not be raised. As a result, in the equipment configured as described above, the splashing of particles onto the wafer 150, to which processing such as etching is carried out, will be eliminated and also the quantity of contaminant caused by the particles will be reduced, and thus semiconductor devices with few defects can be manufactured efficiently.

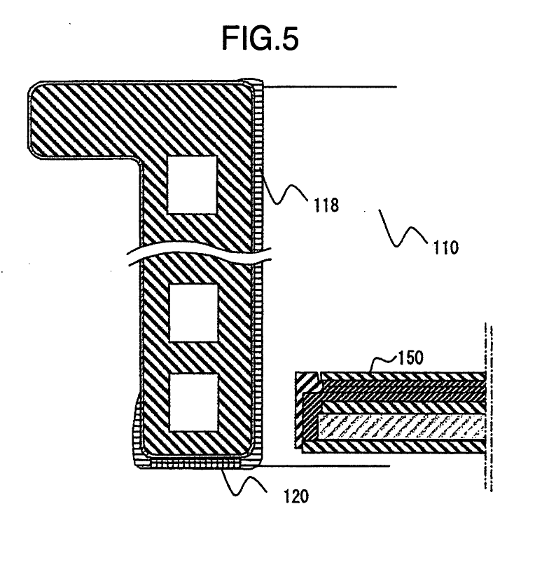

FIG. 5 is an example, in which a plasma resistant resin 120 containing an electrically conductive material is used for a part of the processing chamber wall member 116. In this example, a polymer material, such as polyamidoimide, polyether ether ketone, polyimide, polyetherimide, polytetrafluoroethylene, or polybenzimidazole, is used for the plasma resistance resin 120 containing an electrically conductive material. By using the plasma resistance resin 120 containing this electrically conductive material in a part of the processing chamber wall member 116, the potential of the plasma 200 generated inside the processing chamber 110 will not be raised. As a result, in the equipment configured as described above, the splashing of particles onto the wafer 150, to which processing such as etching is carried out, will be eliminated and also the quantity of contaminant caused by the particles will be reduced, and thus semiconductor devices with few defects can be manufactured efficiently.

According to the above example, the potential of the plasma generated inside the processing chamber will not be raised because a material containing an electrically conductive material is used for a part of the processing chamber. As a result, an abnormal electric discharge that directly hits a part of the plasma sprayed coating film will not occur, and also particles generated by the abnormal electric discharge will not be splashed onto a wafer, to which processing such as etching is carried out. As a result, it is possible to achieve the above-described object of preparing a device with few defects due to particles and due to contamination caused by the particle.

It should be further understood by those skilled in the art that although the foregoing description has been made on embodiments of the invention, the invention is not limited thereto and various changes and modifications may be made without departing from the spirit of the invention and the scope of the appended claims.

1. A plasma etching equipment that employs a plasma process using a halogen-based gas in fabricating a semiconductor device, wherein a plasma sprayed coating film is applied to a surface of a wall, such as a wall in a processing chamber, which plasma is in constant with, and wherein a conductor is incorporated into a material of the plasma sprayed coating film, thereby making the plasma sprayed coating film conductive.

2. The plasma etching equipment according to claim 1, wherein a material sprayed to a wall member inside the plasma processing equipment is composed of either one type, or two or more types out of Al₂O₃, YAG, Y₂O₃, Gd₂O₃, Yb₂O₃, and YF₃, and wherein a conductor is incorporated into the sprayed material.

3. The plasma etching equipment according to claim 1 or 2, wherein the conductor to be incorporated into the member, the member being sprayed to a surface of the wall of the plasma processing equipment, is composed of either one type, or two or more types out of carbon, cobalt, iridium, molybdenum, nickel, osmium, palladium, platinum, rhodium, ruthenium, tantalum, thorium, titanium, vanadium, tungsten, yttrium, and zirconium.

4. The plasma etching equipment according to claim 1, wherein a volume resistivity of the material sprayed to a surface of the wall of the plasma processing equipment is set equal to or less than 100 Ω·cm.

5. The plasma etching equipment according to claim 1, wherein the material sprayed to a surface of the wall of the plasma processing equipment is coated by plasma spray or by low pressure plasma spraying.

6. The plasma etching equipment according to claim 1, wherein a material composed of a conductor, such as a stainless alloy or an aluminum alloy, is used for a base material of the plasma sprayed coating film covering a wall which the plasma inside the processing chamber is in contact with.

7. A plasma processing equipment that employs a plasma process using a halogen-based gas in fabricating a semiconductor device, wherein in a surface of a wall, such as a wall inside a processing chamber, which plasma is in contact with, a sintered ceramic such as alumina, into which either one type, or two or more types of conductors out of carbon, cobalt, iridium, molybdenum, nickel, osmium, palladium, platinum, rhodium, ruthenium, tantalum, thorium, titanium, vanadium, tungsten, yttrium, and zirconium are mixed, is used.

8. A plasma processing equipment that employs a plasma process using a halogen-based gas in fabricating a semiconductor device, wherein in a surface of a wall, such as a wall inside a processing chamber, which plasma is in contact with, quartz, into which either one type, or two or more types of conductors out of carbon, cobalt iridium, molybdenum, nickel, osmium, palladium, platinum, rhodium, ruthenium, tantalum, thorium, titanium, vanadium, tungsten, yttrium, and zirconium are mixed, is used.

9. A plasma processing equipment that employs a plasma process using a halogen-based gas in fabricating a semiconductor device, wherein in a surface of a wall, such as a wall inside a processing chamber, which plasma is in contact with, a plasma resistant resin, into which either one type, or two or more types of conductors out of carbon, cobalt, iridium, molybdenum, nickel, osmium, palladium, platinum, rhodium, ruthenium, tantalum, thorium, titanium, vanadium, tungsten, yttrium, and zirconium are mixed, is used.
